(19) United States
(12) Patent Application Publication
(10) Pub. No.: US 2026/0184084 A1
(43) Pub. Date: Jul. 2, 2026

(54) LIQUID EJECTION HEAD AND LIQUID EJECTING APPARATUS

(71) Applicant: CANON KABUSHIKI KAISHA, Tokyo (JP)

(72) Inventors: TOMOO IIZUMI, Kanagawa (JP); HISAO OKITA, Kanagawa (JP); YUJI TAMARU, Tokyo (JP); KIMIYUKI HAYASAKI, Kanagawa (JP); YOSUKE TAKAGI, Kanagawa (JP)

(21) Appl. No.: 19/429,626

(22) Filed: Dec. 22, 2025

(30) Foreign Application Priority Data
Dec. 26, 2024 (JP) 2024-231016

(51) Int. Cl. B41J 2/175; B41J 2/20; B41J 2/21; B41J 29/393; G01R 19/165

(52) U.S. Cl. CPC B41J 2/17596; B41J 2/20; B41J 2/2103; B41J 29/393; G01R 19/1659; B41P 2251/10

(57) ABSTRACT

A liquid ejection head including a piezoelectric pump for circulating ink, the liquid ejection head comprises a booster circuit configured to generate a boosted voltage for driving the piezoelectric pump in response to a driving signal, a driving circuit configured to generate a pump driving signal for driving the piezoelectric pump based on the boosted voltage, and a monitoring circuit configured to monitor a displacement of a boosted voltage output from the booster circuit. The monitoring circuit readably holds a result of monitoring the boosted voltage.

### BACKGROUND

### Field of the Technology

The present disclosure relates to a liquid ejection head and a liquid ejecting apparatus.

### Description of the Related Art

Recent inkjet printers often use an ink-circulation type liquid ejecting apparatus in order to record an image at high speed using high concentration ink. Such an apparatus employs a configuration in which an ink supply path and an ink recovery path are provided for ink circulation, and a circulation flow of the ink is obtained by generating a differential pressure in the ink supply path and the ink recovery path.

Japanese Patent Laid-Open No. 2023-090450 describes an ink circulation apparatus including two reservoirs for supplying and refluxing ink to a liquid ejection head, a circulation pump for conveying the ink between the reservoirs, a pressure sensor, and a driving circuit for driving the circulation pump in accordance with an output of the pressure sensor.

In the technique described in Japanese Patent Laid-Open No. 2023-090450, the liquid ejection head is provided with a piezoelectric pump including a piezoelectric element in order to circulate a high concentration ink.

The liquid ejection head is mounted with, other than the piezoelectric pump, a driving circuit of the piezoelectric pump, an ink reservoir, and the like, but it is desired to downsize the liquid ejection head in order to downsize the printer.

There is a case where during operation of the piezoelectric pump, a failure such as peeling of an electrode or cracking of a piezoelectric element occurs, and performance as set is not obtained. Japanese Patent Laid-Open No. 2018-117461 describes an abnormality detection circuit that determines normality of a piezoelectric element by measuring a current flowing to the piezoelectric element by adding a shunt resistor and a current detection circuit. However, in such a circuit configuration, a circuit scale increases, which is an obstacle for achieving downsize of the liquid ejection head including the piezoelectric pump.

### SUMMARY

Embodiments of the present disclosure eliminate the above-mentioned issues with conventional technology.

A feature of embodiments of the present disclosure is to provide a technique for detecting whether a piezoelectric pump of a liquid ejection head has failed.

According to embodiments of the present disclosure, there is provided a liquid ejection head including a piezoelectric pump for circulating ink, the liquid ejection head comprising: a booster circuit configured to generate a boosted voltage for driving the piezoelectric pump in response to a driving signal; a driving circuit configured to generate a pump driving signal for driving the piezoelectric pump based on the boosted voltage; and a monitoring circuit configured to monitor a displacement of a boosted voltage output from the booster circuit, wherein the monitoring circuit readably holds a result of monitoring the boosted voltage.

Further features of the various embodiments will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the disclosure and, together with the description, serve to explain the principles of the disclosure.

FIG. 1A depicts a schematic perspective view of a configuration example of a liquid ejecting apparatus using a liquid ejection head 1 according to an embodiment.

FIG. 1B is a block diagram for describing an outline of a control unit that controls the liquid ejecting apparatus and a configuration controlled by the control unit.

FIG. 2 depicts an exploded perspective view illustrating a configuration of the liquid ejection head according to the embodiment.

FIG. 3 depicts a schematic external view of one of ink circulation units applied to an inkjet recording apparatus according to the embodiment.

FIG. 4 is a schematic diagram for describing a circulation path of ink for one color applied to the inkjet recording apparatus according to the embodiment.

FIG. 5 is a schematic diagram of an electric connection configuration for driving a circulation pump (piezoelectric pump) used for ink circulation.

FIGS. 6A to 6C depict views for describing an operation of the circulation pump according to the embodiment.

FIG. 7 depicts a view illustrating a configuration example of an ink circulation circuit in a case where the inkjet recording apparatus according to the embodiment executes monochrome printing.

FIG. 8 is a schematic diagram of an ink circulation circuit example of the present disclosure.

FIG. 9 depicts a view illustrating a specific circuit example of a booster circuit according to the embodiment.

FIG. 10 depicts a view illustrating a circuit example of a driver circuit according to the embodiment.

FIG. 11 depicts a view illustrating an example of displacement of a pump driving voltage at the time of printing in the inkjet recording apparatus according to the embodiment.

FIG. 12 depicts a view illustrating an example of displacement of a pump driving voltage at the time of diagnosis in the inkjet recording apparatus that is a feature of the embodiment.

FIG. 13 is a flowchart for describing processing when diagnosis processing of the circulation pump is performed in the inkjet recording apparatus according to the embodiment.

FIG. 14 depicts a view illustrating a circuit example for performing operation check of each circulation pump when using a plurality of circulation pumps.

### DESCRIPTION OF THE EMBODIMENTS

Example embodiments of the present disclosure will be described hereinafter in detail, with reference to the accompanying drawings. It is to be understood that the following embodiments are not intended to limit the claims of the present disclosure, and that not all of the combinations of the aspects that are described according to the following embodiments are necessarily required with respect to the means to solve the issues according to the present disclosure. Further, in the accompanying drawings, the same or similar configurations are assigned the same reference numerals, and redundant descriptions are omitted.

In the embodiment, an example in which a thermal method of generating air bubbles by an electrothermal conversion element and ejecting liquid is adopted as an ejection element that ejects liquid will be described, but the present disclosure is not limited to this. The present disclosure can also be applied to a liquid ejection head adopting an ejection method of ejecting liquid using a piezoelectric element (piezo) or another ejection method. Furthermore, the pump, the pressure adjusting means, and the like described below are not limited to the configurations described in the embodiments and the drawings.

First, terms used in the present embodiment are defined as follows in advance.

“Recording (printing)”

In this specification, “recording (printing)” is not only forming significant information such as letters, shapes, and the like. The significance or insignificance is irrelevant, as is whether visual perception by humans is possible. It refers to forming images, designs, patterns, and the like broadly on a recording medium, as well as processing the medium.

### “Recording Media”

Recording media refers not only to paper used in general printing apparatuses, but also broadly to those that can receive ink, such as cloth, plastic films, metal plates, glass, ceramics, wood, and leather.

### “Ink”

Ink is to be interpreted broadly, similar to the definition of “recording (printing)” above, and refers to a medium that includes a recording agent which, by being applied to a recording medium, forms images, designs, patterns, and the like, or which may be supplied in processing of a recording medium, or processing of ink. In terms of physical properties, it is a liquid. The above ink processing is, for example, coagulation or insolubilization of a colorant in an ink applied to a recording medium.

### “Nozzle”

Unless otherwise specified, “nozzle” refers to a discharge port. Inside the nozzle, there are communicating liquid paths and an element that generates energy used for ink discharge.

### “Nozzle”

Unless otherwise specified, “nozzle” refers to a discharge port. Inside the nozzle, there are communicating liquid paths and an element that generates energy used for ink discharge.

### “Scanning”

In order to perform recording on a recording medium, a print head scans over the recording medium and performs recording. Here, the movement of the head during acceleration and deceleration of the head for or related to recording is referred to as scanning.

### EMBODIMENTS

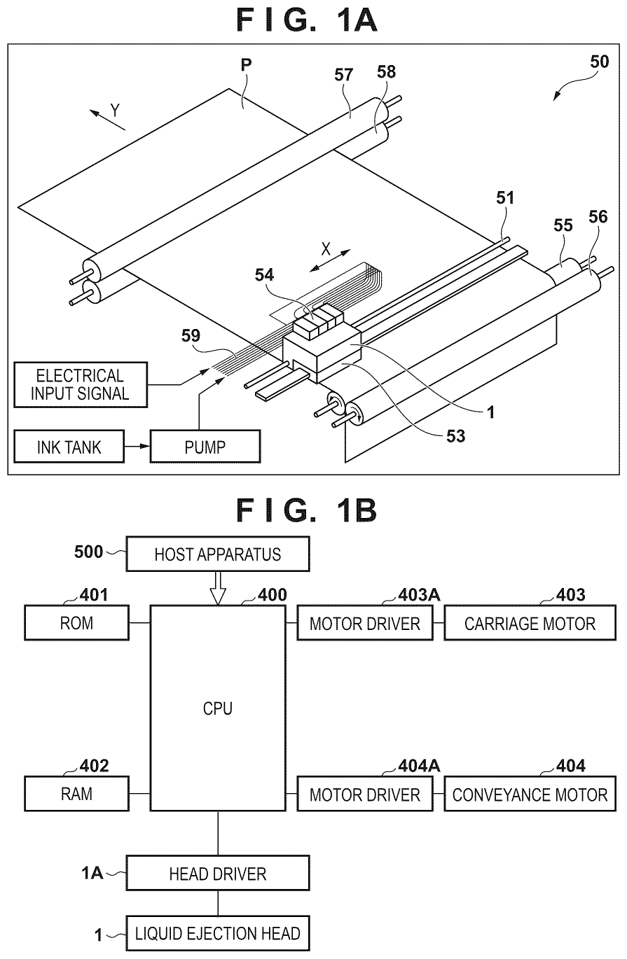

FIG. 1A depicts a schematic perspective view for describing a configuration example of a liquid ejecting apparatus using the liquid ejection head 1 according to the embodiment, and FIG. 1B is a block diagram for describing an outline of a control unit that controls the liquid ejecting apparatus and a configuration controlled by the control unit.

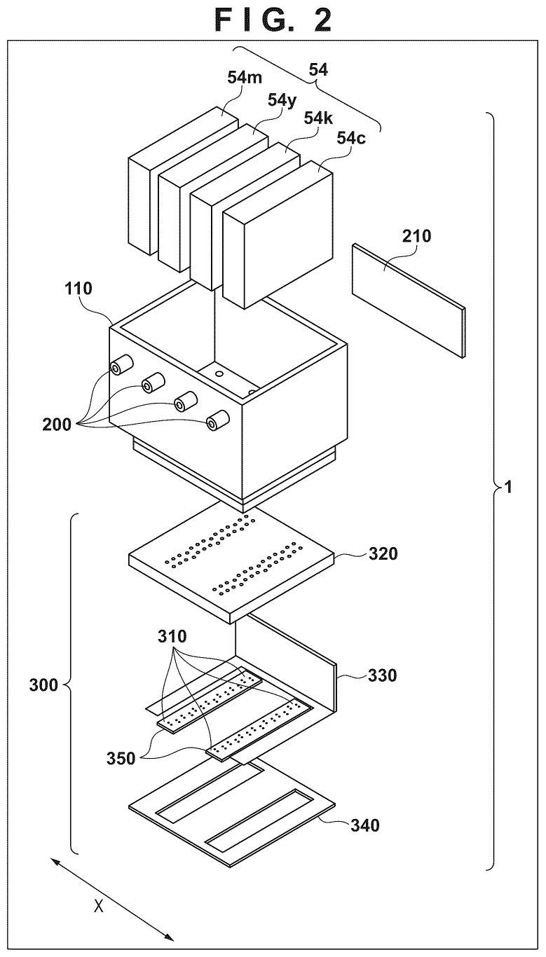

The liquid ejecting apparatus according to the embodiment is an inkjet recording apparatus 50 of a serial scan type that ejects ink from the liquid ejection head 1 to record (print) an image on a recording medium P. The liquid ejection head 1 as an inkjet head is mounted on a carriage 53, and the carriage 53 can reciprocate in a main scanning direction of an arrow X along a guide shaft 51. The recording medium P is conveyed by conveyance rollers 55, 56, 57, and 58 in a sub-scanning direction of an arrow Y intersecting (orthogonal in the case of the present example) the main scanning direction. The liquid ejection head 1 is mounted with an ink circulation unit 54, and ink circulation in an ejection unit 300 (FIG. 2) described later is performed. An ejection energy generating element included in the ejection unit 300 is driven by a head driver 1A (FIG. 1B) in response to an input signal from an electric connection substrate. Electric wiring necessary for ejecting ink, and pipe arrangements of ink and air are connected to the carriage 53 via a guide 59, and electric signals, ink and air are supplied to the carriage 53.

A control unit (CPU) 400 controls the inkjet recording apparatus 50 based on a program including a code describing a processing procedure and the like stored in a ROM 401, and a RAM 402 is used as a work area or the like for executing such processing. Upon receiving a job including image data from a host apparatus 500 outside the inkjet recording apparatus 50, the CPU 400 drives and controls the head driver 1A in accordance with the job to record an image. At the time of recording, the CPU 400 controls driving of a carriage motor 403 for moving the carriage 53 via a motor driver 403A, and controls driving of a conveyance motor 404 for conveying the recording medium P via a motor driver 404A.

The liquid ejection head 1 can perform full-color printing using cyan, magenta, yellow, and black (CMYK) inks for color printing. Note that configurations for performing monochrome printing includes a configuration for recording using only the K ink for monochrome printing or a configuration of the recording apparatus only provided with a K ink ejection head. A cap member (not illustrated) is arranged at a position deviated from the conveyance path of the recording medium P. When no recording operation is performed, drying of an ejection orifice is prevented by moving the cap member or the liquid ejection head 1 to a position where the cap member covers a face surface of the liquid ejection head 1. In a state where the cap member covers the face surface of the liquid ejection head 1, a filling operation of ink and a suction operation for recovering from ink ejection failure can be performed.

FIG. 2 depicts an exploded perspective view illustrating the configuration of the liquid ejection head 1 according to the embodiment.

As illustrated in FIG. 2, the liquid ejection head 1 includes the ink circulation unit 54. The circulation unit 54 includes circulation units 54m, 54y, 54k, and 54c corresponding to respective inks, and the respective circulation units 54 are connected to a flow path member 110. Here, m, y, k, and c correspond to the colors of inks described above. A connection method of the circulation unit 54 and the flow path member 110 may be a screw fastening method in which a seal member is sandwiched therebetween, or a connection by welding. The flow path member 110 includes a joint 200 for receiving ink from a main body of the inkjet recording apparatus 50, and the joint 200 is in communication so as to be connected to each of the circulation units 54m, 54y, 54k, and 54c.

When the liquid ejection head 1 is mounted to the main body of the inkjet recording apparatus 50, a supply tube (not illustrated) corresponding to each ink is connected to each joint 200 from the main body side of the recording apparatus 50. Then, the inks supplied through the supply tube are supplied to the circulation units 54m, 54y, 54k, and 54c, respectively, via the joint 200 of the flow path member 110. The ejection unit 300 is connected to the bottom surface of the flow path member 110, and the ink supplied to the circulation unit 54 is supplied to the ejection unit 300 via the flow path member 110.

The ejection unit 300 includes an ejection element 310 including an actuator for ejecting ink, a support member 320, an electric wiring substrate 330 for sending electric signals to the ejection element 310 on an ejection element substrate 350, and a cover member 340 covering the electric wiring substrate 330. The ejection element 310 and the electric wiring substrate 330 are bonded and fixed to the support member 320, and the cover member 340 is bonded and joined so as to cover the surface of the ejection element substrate 350. The ejection element 310 and the electric wiring substrate 330 are electrically connected by wire bonding. Here, the electric connection method may be, for example, flying lead bonding. In the cover member 340, a portion corresponding to the ejection element 310 is an opening. The connection method between the ejection unit 300 and the flow path member 110 may be bonding using an adhesive or fixing by screw fastening in which a seal member is sandwiched.

An opposite surface of the joint 200 of the flow path member 110 is a contact surface, and a head substrate 210 that receives an electric signal from the main body is connected to the contact surface. Electric signals are sent from this head substrate 210 to the ejection element 310 via the electric wiring substrate 330 of the ejection unit 300. At this time, the connection between the head substrate 210 and the flow path member 110 may be fixing with caulking or an adhesive, or fixing with a double-sided adhesive tape. The electric connection between the head substrate 210 and the electric wiring substrate 330 is formed by, for example, electric connection processing anisotropic conductive film (ACF) pressure bonding using an ACF.

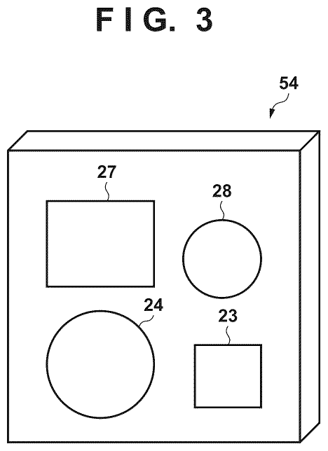

FIG. 3 depicts a schematic external view of one of the ink circulation units 54 applied to the inkjet recording apparatus 50 according to the embodiment.

One ink circulation unit 54 is arranged per color, and includes a first pressure control mechanism 24, a second pressure control mechanism 28, a filter 23, and a circulation pump 27 (piezoelectric pump) used for circulation of ink.

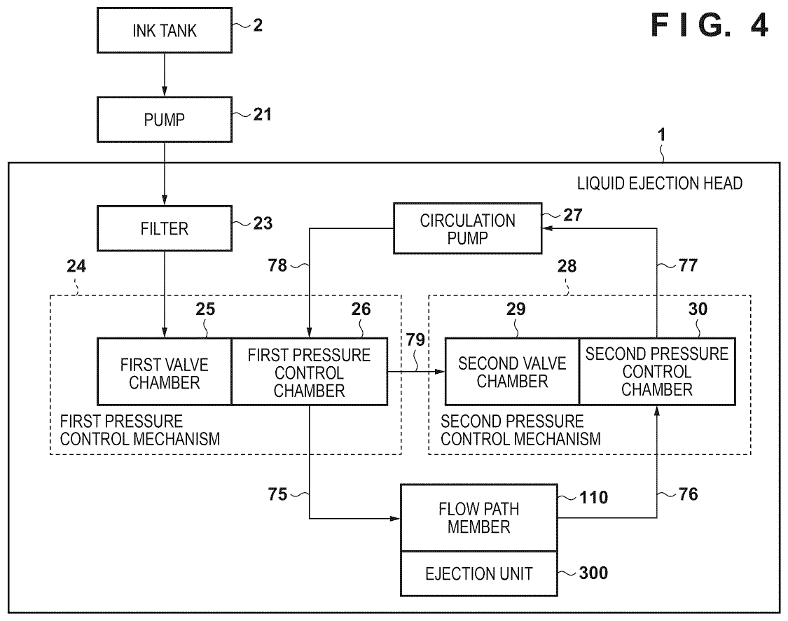

FIG. 4 is a schematic diagram for describing a circulation path of ink for one color applied to the inkjet recording apparatus 50 according to the embodiment.

The ink is pressurized and supplied by a pump 21 from an ink tank 2 to the liquid ejection head 1. After dust is removed by the filter 23, the supplied ink is supplied to a first valve chamber 25 of the first pressure control mechanism 24. Thereafter, the pressure of the ink is adjusted when the ink flows into a first pressure control chamber 26 communicating with the first valve chamber 25 via a valve. The ink whose pressure in the first pressure control chamber 26 is adjusted is supplied to a supply flow path 75 and a bypass flow path 79 by drive of the circulation pump 27. The supply flow path 75 is a flow path including the flow path member 110, and is connected to the ejection unit 300 of the liquid ejection head 1. A recovery flow path 76 is also a flow path including the flow path member 110, and is connected to the ejection unit 300. The ink supplied to the supply flow path 75 passes through the ejection element 310 formed on the ejection element substrate 350 of the ejection unit 300 and is ejected onto the recording medium P to form an image. Then, remaining ink is discharged from the flow path member 110 to the recovery flow path 76, and is finally supplied to a second pressure control chamber 30 of the second pressure control mechanism 28. In the second pressure control mechanism 28, the ink supplied to a second valve chamber 29 is further supplied to the second pressure control chamber 30 communicating with the second valve chamber 29 via a valve. The ink supplied to the second pressure control chamber 30 is supplied to a pump inlet flow path 77, passes through the circulation pump 27, and then is supplied to a pump outlet flow path 78. Thereafter, the ink is further supplied to the first pressure control chamber 26. In this manner, with the circulation pump 27, the ink having passed through the ejection element 310 circulates in this manner, thereby enabling suppression of the thickening of the ink of the ejection element 310. Note that this circulation path is not limited to the configuration through the ejection element 310, and may be configured to circulate the ink in the ejection unit 300 within a range having an effect of suppressing the ink thickening in the ejection element 310.

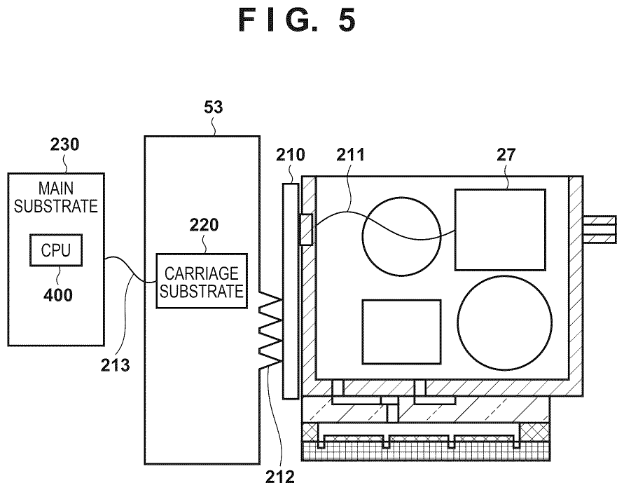

FIG. 5 is a schematic diagram of an electric connection configuration for driving the circulation pump 27 used for ink circulation.

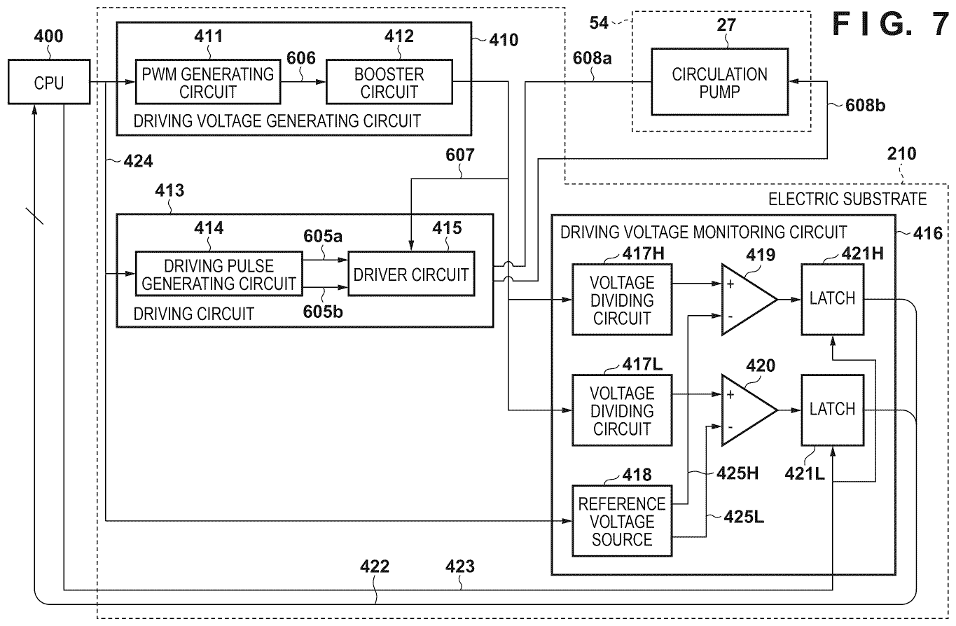

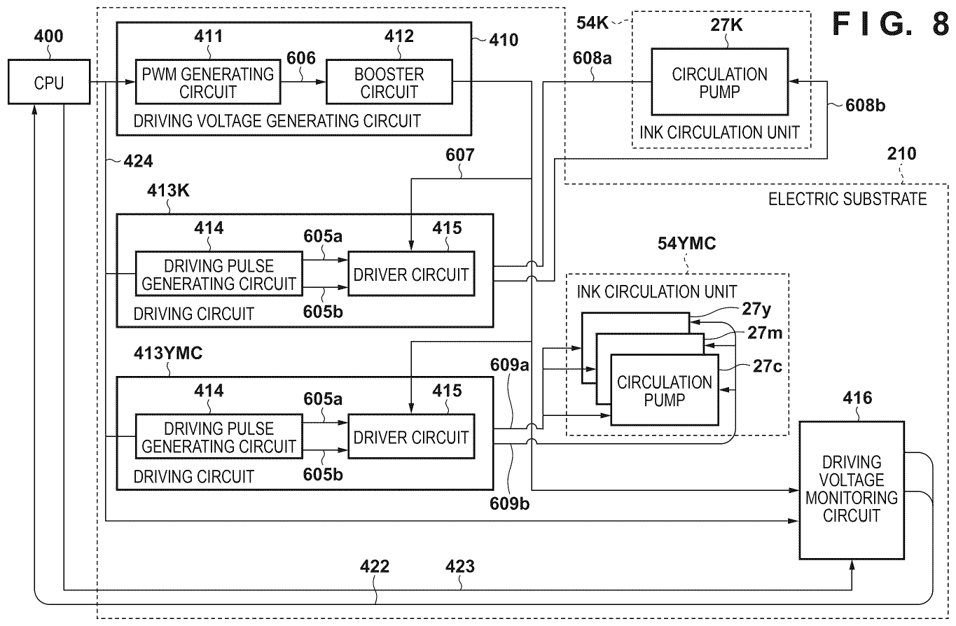

A driving signal is sent via a cable 213 to the carriage substrate 220 from the CPU 400 mounted on a main substrate 230 present in the inkjet recording apparatus 50. Furthermore, the driving signal is sent from the carriage substrate 220 to the head substrate 210 via an electric connection portion 212 by contact connection. Here, the head substrate 210 is mounted with a control chip, a booster circuit, a voltage dividing circuit, and the like. When the control chip receives the driving signal from the carriage substrate 220, the booster circuit is driven by outputting a PWM waveform. Here, the booster circuit boosts an input voltage of, for example, 5 V to about 70 V. The voltage thus boosted is controlled by a driving circuit 413 (FIG. 7) on the head substrate 210 and output to the circulation pump 27 via a harness wiring 211 (including 608a and 608b in FIGS. 7 and 609a and 609b in FIG. 8), and the circulation pump 27 operates to circulate the ink.

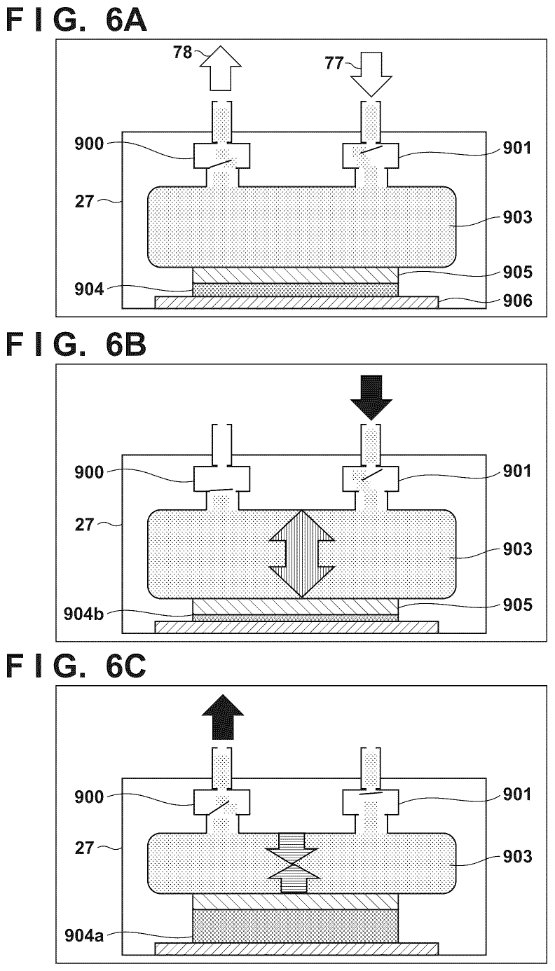

FIGS. 6A to 6C depict views for describing the operation of the circulation pump 27 according to the embodiment.

FIG. 6A depicts a view illustrating the configuration of a piezoelectric pump, which is an example of the circulation pump 27 according to the embodiment. The circulation pump 27 changes the shape of an ink chamber 903, which is a diaphragm, in accordance with deformation of a piezoelectric element 904. The circulation pump 27 includes an upper electrode 905 and a lower electrode 906 arranged so as to sandwich the piezoelectric element 904, and a check valve 900 that prevents back flow to the pump outlet flow path 78 when ink is taken in from the pump inlet flow path 77 to the ink chamber 903. The circulation pump 27 further includes a suction check valve 901 that prevents the ink from flowing out to the pump inlet flow path 77 when the ink is sent to the pump outlet flow path 78. Due to the deformation of the piezoelectric element 904, ink is taken in from the pump inlet flow path 77 and output to the pump outlet flow path 78. This is alternately repeated to convey the ink.

FIG. 6B depicts a view illustrating a state when the circulation pump 27 sucks ink.

To suck the ink, a voltage is applied to the upper electrode 905 and the lower electrode 906 so that the piezoelectric element 904 contracts. As a result, the ink chamber 903 expands so as to increase its volume. This brings into a state where the ink chamber 903 is filled with ink via the check valve 901.

FIG. 6C depicts a view illustrating a state when the circulation pump 27 outputs ink.

A voltage is applied so that the piezoelectric element 904 expands, whereby the ink chamber 903 contracts, and the ink in the ink chamber 903 is output from the check valve 900 to the pump outlet flow path 78.

FIG. 7 depicts a view illustrating a configuration example of an ink circulation circuit in a case where the inkjet recording apparatus 50 according to the embodiment executes monochrome printing.

The CPU 400 controls the entire apparatus, and issues via a setting bus 424 an instruction for a driving voltage generating circuit 410 to boost or an instruction for the driving circuit 413 to operate.

The driving voltage generating circuit 410 generates a high voltage for driving the circulation pump 27. In accordance with an instruction from the CPU 400, a PWM generating circuit 411 generates and inputs, to a booster circuit 412 as a PWM signal 606, a pulse width modulation (PWM) waveform signal of a designated period and duty.

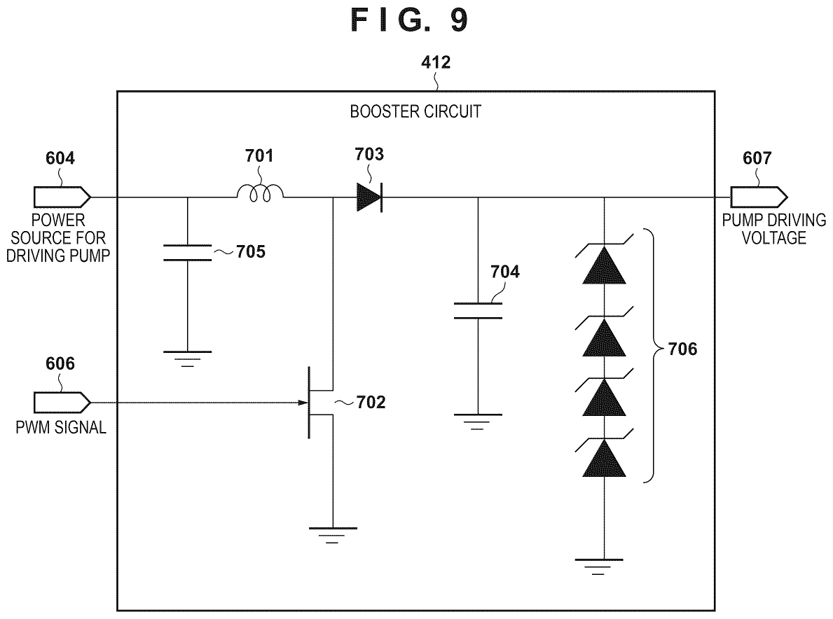

FIG. 9 depicts a view illustrating a specific circuit example of the booster circuit 412 according to the embodiment.

A power source voltage input from a pump drive power source 604 is input to an inductor 701, and a switching element 702 connected to another terminal of the inductor 701 is turned on/off in accordance with the PWM signal 606. Energy is stored in the inductor 701 when the switching element 702 is on, and a voltage boosted from a diode 703 is output to a capacitor 704 and a pump driving voltage 607 when the switching element 702 is off.

A zener diode 706 is connected so that the pump driving voltage 607 does not become a predetermined voltage or more. Here, for example, four zener diodes of 18 V are connected in series, and when the pump driving voltage 607 becomes 72 V or more, a current flows to GND, whereby the pump driving voltage 607 does not become 72 V or more. A bypass capacitor 705 suppresses switching noise generated in the inductor 701.

In this manner, in this booster circuit 412, the higher the repetition frequency of the PWM signal 606 is and the larger the duty of the PWM signal 606 is, the larger power is generated for driving the pump.

Returning to FIG. 7, the driving circuit 413 includes a driving pulse generating circuit 414 and a driver circuit 415. Depending on the setting from the CPU 400, the driving pulse generating circuit 414 outputs, to the driver circuit 415 as pump control signals 605a and 605b, a pulse signal necessary for driving the piezoelectric pump of the circulation unit 54 and a pulse signal whose polarity is inverted. The pump control signals 605a and 605b repeatedly transition between, for example, 3.3 V and the GND voltage in accordance with a period designated by the CPU 400.

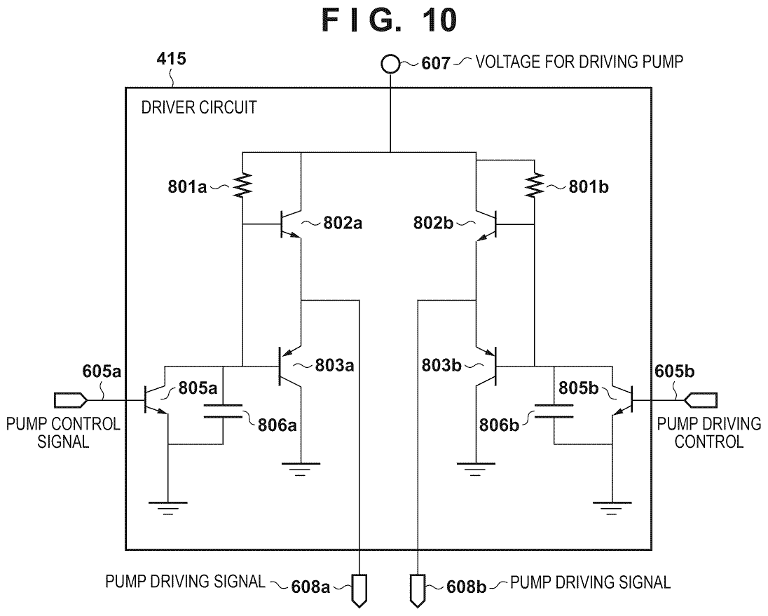

FIG. 10 depicts a view illustrating a circuit example of the driver circuit 415 according to the embodiment.

The pump driving voltage 607 is connected to resistors 801a and 801b and collectors of transistors 802a and 802b. In the embodiment, NPN transistors are used as the transistors 802a and 802b. Emitters of transistors 803a and 803b are connected to emitters of the transistors 802a and 802b, respectively. Transistors 803a and 803b use PNP transistors. The pump driving signal 608a is connected to the emitter of the transistor 802a and the emitter of the transistor 803a. The pump driving signal 608b is connected to the emitter of the transistor 802b and the emitter of the transistor 803b.

The resistor 801a is connected to a base of the transistor 802a, a base of the transistor 803a, a collector of a transistor 805a, and a capacitor 806a. The resistor 801b is connected to a base of the transistor 802b, a base of the transistor 803b, a collector of a transistor 805b, and a capacitor 806b. The transistors 805a and 805b use NPN transistors.

The pump control signal 605a output from the driving pulse generating circuit 414 is connected to the base of the transistor 805a. When the pump control signal 605a becomes a low level potential in a state where the pump driving voltage 607 is input, the potentials of the base of the transistor 802a and the base of the transistor 803a become the pump driving voltage 607 via the resistor 801a. As a result, the transistor 802a is brought into an on state (active), and the transistor 803a is brought into an off state (inactive). As a result, a current flows from the pump driving voltage 607 to the pump driving signal 608a.

On the other hand, the pump control signal 605b is in the reversed phase of the pump control signal 605a, and becomes the high level when the pump control signal 605a is the low level. Therefore, at this time, the transistor 805b becomes active, and the base of the transistor 802b and the base of the transistor 803b is at the ground voltage. As a result, the transistor 802b becomes inactive, and the transistor 803b becomes active, and therefore the pump driving signal 608b is pulled to the ground potential. Since the transistors 802a and 802b, 803a and 803b, and 805a and 805b are symmetrical, the pump control signals 605a and 605b alternately change between the pump driving voltage 607 and the ground level.

As a result, the pump driving signals 608a and 608b simultaneously increase the voltage to the pump driving voltage 607 and decrease the voltage to the ground level at the changing point of the pump control signals 605a and 605b.

At this time, the circulation pump 27, which is a load of the pump driving signals 608a and 608b, is applied with the voltage of the change of the pump driving signals 608a and 608b, and applied with a voltage having a width twice as large as the pump driving voltage 607.

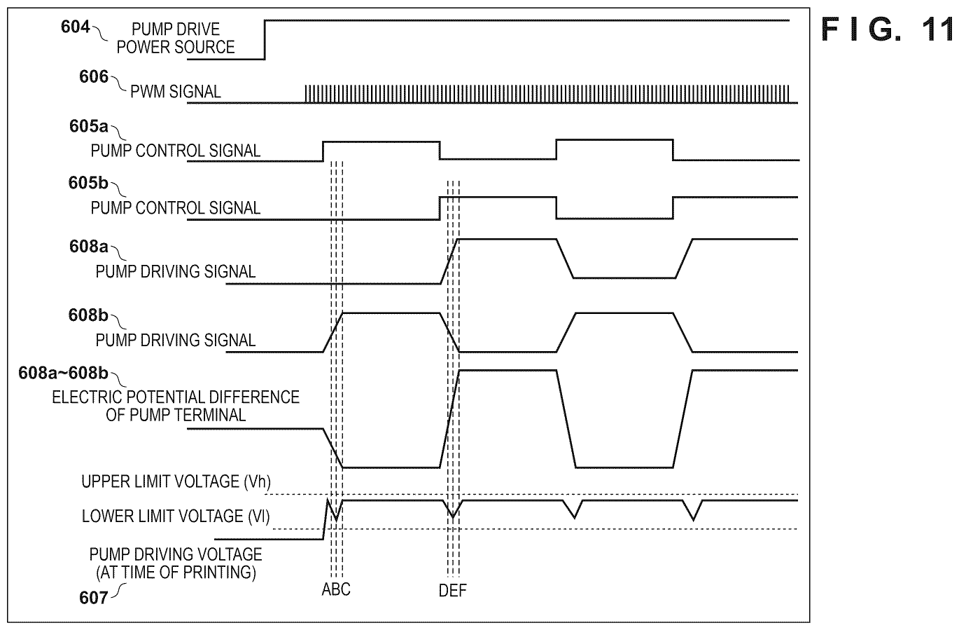

As illustrated in FIG. 9, the pump driving voltage 607 is connected to the capacitor 704 to charge the capacitor 704. When a change of the terminal voltage of the pump occurs by operating the circulation pump 27, the polarity charged between the upper electrode 905 and the lower electrode 906 until then is switched. As a result, a current flows through the driver circuit 415, and the pump driving voltage 607 temporarily decreases the voltage (sections A to B and D to E in FIG. 11). If the power sent from the power source to the capacitor 704 by the PWM waveform is sufficiently charged for driving, drop of the driving voltage 607 is small. The dropping voltage width is proportional to the electrostatic capacitance of the circulation pump 27, and the larger the electrostatic capacitance is, the larger the current flowing due to the polarity change of the pump terminal voltage becomes, and therefore the pump driving voltage 607 drops greatly. Since the pump terminal voltage continues to be supplied with charges from the booster circuit 412 also after the polarity to the circulation pump 27 changes, the pump terminal voltage is recovered to the original pump driving voltage again after the terminal voltage decreases once (sections B to C and E to F in FIG. 11).

FIG. 11 depicts a view illustrating an example of displacement of the pump driving voltage 607 at the time of printing in the inkjet recording apparatus 50 according to the embodiment.

As described above, the booster circuit 412 generates the pump driving voltage 607 corresponding to the repetition frequency and the duty of the output PWM signal 606. Then, by the pump control signals 605a and 605b output from the driving pulse generating circuit 414, the driver circuit 415 outputs the pump driving signals 608a and 608b for increasing the voltage up to the pump driving voltage 607 and decreasing the voltage to the ground level at the changing points of the pump control signals 605a and 605b. In this manner, the terminal of the circulation pump 27 is applied with the voltage of the change of the pump driving signals 608a and 608b, and applied with a voltage having a width twice as large as the pump driving voltage 607.

As described above, the states indicated by the sections A to B and D to E of the pump driving voltage 607 in FIG. 11 indicate a state in which the circulation pump 27 operates to switch the polarity of the terminal voltage, whereby a current flows through the driver circuit 415, and the pump driving voltage 607 temporarily decreases. The sections B to C and E to F in FIG. 11 indicate a state in which the polarity to the circulation pump 27 changes, the terminal voltage once decreases, and then the pump driving voltage is recovered again to the original pump driving voltage. An upper limit voltage Vh and a lower limit voltage Vl of the pump driving voltage 607 are reference voltages for determining whether a failure described later has occurred.

A driving voltage monitoring circuit 416 in FIG. 7 is a monitoring circuit of the pump driving voltage 607, and is a circuit for checking whether the pump driving voltage 607 is a set voltage. The pump driving voltage 607 is divided by voltage dividing circuits 417H and 417L and converted into a low voltage for determination by comparators 419 and 420. Each of the comparators 419 and 420 compares a reference voltage 425 supplied from a reference voltage source 418 with a divided pump driving voltage. The reference voltage source 418 supplies the comparators 419 and 420 with a first reference voltage 425H and a second reference voltage 425L having different potentials in response to an instruction from the CPU 400. When the output voltage of the voltage dividing circuit 417H is larger than the first reference voltage 425H, the output of the comparator 419 becomes the high level and sets a latch 421H. On the other hand, when the output voltage of the voltage dividing circuit 417L becomes the second reference voltage 425L or less, the output of the comparator 420 becomes the high level and sets a latch 421L. Latch data of the latches 421H and 421L is read from the CPU 400 via a reading bus 422. The latch data is cleared by a latch clear 423 from the CPU 400. In this manner, in a predetermined period, it is monitored whether the pump driving voltage 607 falls below the set voltage during a falling edge or exceeds the set voltage during a rising edge, and the CPU 400 can hold the result in a readable manner.

At the time of operation, the comparator 419 is set so as to detect a voltage slightly higher than the voltage of the pump driving voltage 607, and is set to the upper limit voltage Vh (corresponding to the first reference voltage 425H) in FIG. 11, for example. The comparator 420 is set so as to be able to detect a voltage falling to some extent from the voltage of the pump driving voltage 607, for example, the lower limit voltage Vl (corresponding to the second reference voltage 425L) in FIG. 11. As a result, when circulation pump 27 operates, it is detected whether the pump driving voltage 607 is within a range of a set voltage having been set, thereby monitoring whether the circulation pump 27 is normally operating. In a failure captured by this configuration, for example, when the zener diode 706 of the booster circuit 412 in FIG. 9 fails and is brought into an open state, the pump driving voltage 607 exceeds the first voltage having been set. This is detected by the comparator 419, and the latch 421H is set. Then, the CPU 400 is able to detect this failure by reading the latch 421H. In another example, when the inductor 701 of the booster circuit 412 in FIG. 9 has a disconnection failure, the pump driving voltage 607 does not rise from the ground potential and does not reach the set second voltage, and the comparator 420 sets the latch 421L. Then, the CPU 400 is able to detect this failure by reading the latch 421L.

As described with reference to FIG. 6, the circulation pump 27 outputs ink using deformation of the piezoelectric element 904. Cracking of the piezoelectric element 904 itself due to long-term use or the like, a failure of the circulation pump 27 due to cracking or deformation of the upper electrode 905 or the lower electrode 906, disconnection of wiring of the pump driving signals 608a and 608b from the driving circuit 413, or the like are assumed.

It is possible to increase the reliability by detecting such failures in a preparation period after the inkjet recording apparatus 50 is powered on or before printing is started to make a determination so that normal printing can be performed by taking appropriate measures such as replacement of the liquid ejection head.

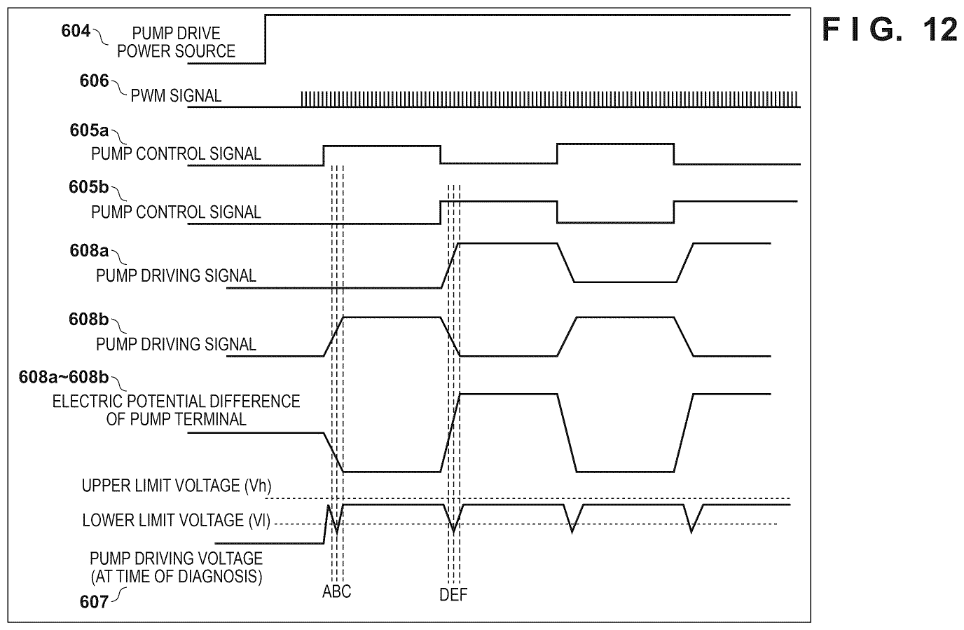

FIG. 12 depicts a view illustrating an example of displacement of the pump driving voltage 607 at the time of diagnosis in the inkjet recording apparatus 50, which is a feature of the embodiment of the present disclosure.

In the assumed detection of the failure of the circulation pump 27, the CPU 400 sets the PWM signal 606 to a waveform different from the PWM waveform at the time of printing illustrated in FIG. 11. In FIG. 12, for example, the duty of the PWM signal 606 is set in the PWM generating circuit 411 so as to be lower than that in the case of FIG. 11. Then, in that state, the booster circuit 412 is driven to generate the pump driving voltage 607. Subsequently, the driving pulse generating circuit 414 is operated to output operation signals to the pump control signals 605a and 605b to the driver circuit 415.

Here, similarly to timings A and D in FIG. 11, the pump driving voltage 607 temporarily decreases as indicated by timings B and E in FIG. 12 by switching the signal applied to the circulation pump 27. In FIG. 12, the waveform of the PWM signal 606 is different from that at the time of operation illustrated in FIG. 11, and the voltage temporarily drops more largely as illustrated in the sections A to C and the sections D to F in FIG. 12. Here, if the electrostatic capacitance of the circulation pump 27 is large, the pump driving voltage 607 falls below the lower limit voltage (Vl), and the comparator 420 detects it, and sets the latch 421L. By the CPU 400 reading the latch 421L, it is possible to detect that the circulation pump 27 has a normal electrostatic capacitance. Conversely, if the pump driving voltage 607 does not fall below the lower limit voltage (Vl), it is possible to determine the failure of the circulation pump 27 as described above.

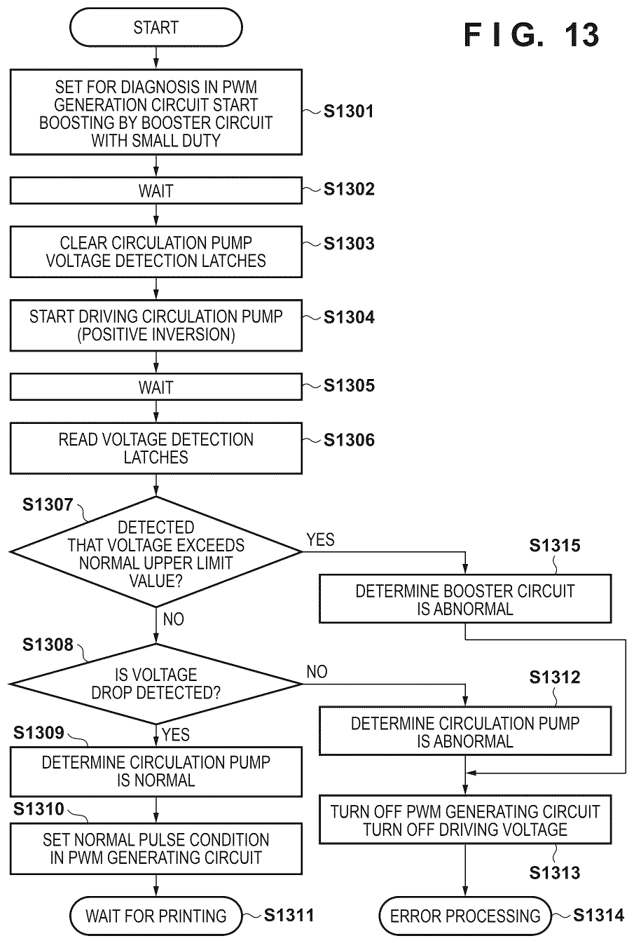

FIG. 13 is a flowchart for describing processing when the diagnosis processing of the circulation pump 27 is performed in the inkjet recording apparatus 50 according to the embodiment. This processing is implemented by the CPU 400 of the control unit executing a program stored in the ROM 401.

First, in step S1301, by setting the frequency and the duty of the PWM signal 606 for diagnosis in the PWM generating circuit 411 to generate the PWM signal 606, the CPU 400 starts boosting by the booster circuit 412. Next, the process proceeds to step S1302, and the CPU 400 waits until the boosted voltage output from the booster circuit 412 becomes a target value. At the timing at which the boosted voltage becomes the target value, the process proceeds to step S1303, and the CPU 400 outputs the latch clear 423 to clear the latches 421H and 421L of the driving voltage monitoring circuit 416. Next, the process proceeds to step S1304, and the CPU 400 activates the driving circuit 413 to start the operation of the circulation pump 27. Then, the CPU 400 waits at step S1305 until the polarities of the pump driving signals 608a and 608b applied to the circulation pump 27 for a predetermined number of times are determined.

Then, the process proceeds to step S1306, the CPU 400 reads the values of the latches 421H and 421L via the reading bus 422, and the process proceeds to step S1307. In a case where the CPU 400 determines in step S1307 that the latch 421H is set and the boosted voltage exceeds the normal upper limit value, the process proceeds to step S1315, the CPU 400 determines an abnormality in the booster circuit 412, and the process proceeds to error processing in step S1313. In step S1315, the CPU 400 stops the operations of the booster circuit 412 and the driving circuit 413 to end the diagnosis, and the process proceeds to error processing in step S1314.

On the other hand, when the CPU 400 determines in step S1307 that the boosted voltage does not exceed the normal upper limit value, the process proceeds to step S1308. In step S1308, the CPU 400 diagnoses the circulation pump 27. Here, the circulation pump 27 has a target electrostatic capacitance, and it is determined, based on the latch data of the latch 421L, whether the drop of the boosted voltage at the time of polarity inversion is as assumed or less. Here, when the latch 421L is not set, that is, when there is no trace of a drop to the set voltage, the process proceeds to step S1312. In step S1312, the CPU 400 determines that the circulation pump 27 is abnormal, the process proceeds to step S1313, and the CPU 400 performs similar processing to that described above.

On the other hand, when the CPU 400 determines in step S1308 that the latch 421L is set, the process proceeds to step S1309, and the CPU 400 determines that the circulation pump 27 is normal. In this manner, when the electrode of the circulation pump 27 is applied with a normal voltage and polarity inversion is performed for driving, the boosted voltage decreases to a voltage lower than the reference value, whereby it is possible to determine that the electrostatic capacitance of the circulation pump 27 is normal as assumed. Then, the process proceeds to step S1310, and the CPU 400, in preparation for printing, sets the frequency and the duty of the PWM signal 606 for printing in the PWM generating circuit 411 and then generates the PWM signal 606. Then, the process proceeds to step S1311, and the state transitions to a print waiting state in which the start of printing is awaited.

As described above, according to this processing, the PWM waveform used for boosting is changed for diagnosis from that at the time of printing, and a decrease width of the boosted voltage at the time of switching the polarity of the driving voltage applied to the electrode of the circulation pump is increased. The circuit that detects the decrease width can be configured with a simple circuit including a comparator to determine whether the electrostatic capacitance of the circulation pump is normal, that is, whether the circulation pump is normal.

FIG. 8 depicts a view illustrating a configuration example of an ink circulation circuit in a case where the inkjet recording apparatus 50 according to the embodiment executes color printing. Portions common to those in FIG. 7 described above are denoted by the same reference numerals, and description thereof will be omitted. In FIG. 8, while using the driving voltage generating circuit 410 that is common, two systems of driving circuits 413K and 413YMC of K and YMC, respectively, drive circulation pumps 27k, 27y, 27m, and 27c. The basic operation of this circuit is basically the same as that described with reference to FIG. 7. In FIG. 8, each of the three circulation pumps 27y, 27m, and 27c is driven by the pump driving signals 609a and 609b output from the driving circuit 413YMC. The circulation pump 27k for black ink is driven by the pump driving signals 608a and 608b output from the driving circuit 413K. The configurations and operations of the driving circuit 413YMC and the driving circuit 413K are the same as those of the driving circuit 413 described above.

In a case of monochrome printing, only the circulation pump 27k is driven, and in a case of color printing, the three circulation pumps 27y, 27m, and 27c are driven by one driving circuit 413YMC, whereby monochrome printing and color printing are established with a small number of components.

In a case where circulation pumps of the same specifications are used in the ink circulation units 54K and 54YMC, the electrostatic capacitance of the circulation pump becomes ⅓ in the monochrome printing using only the circulation pump 27k compared to the printing in YMC using the three circulation pumps 27y, 27m, and 27c. Therefore, in a case where measurement is performed only with the circulation pump 27k, since the electrostatic capacitance is smaller than that of printing in YMC, the duty of the PWM signal 606 is made smaller than that in the case of YMC to perform the measurement.

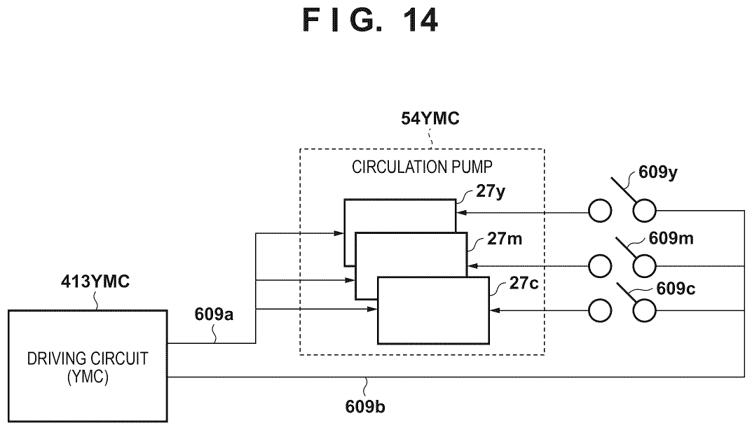

FIG. 14 depicts a view illustrating an example in which switches 609y, 609m, and 609c, that can be independently connected/disconnected at the time of diagnosis of YMC in which the three circulation pumps 27y, 27m, and 27c are driven by one driving circuit 413YMC, are added to the three pump driving signals 609a. By turning on/off these switches 609y, 609m, and 609c in response to a control signal (not illustrated) from the CPU 400, whereby it is possible to select a circulation pump of a diagnosis target. As a result, at the time of diagnosis, by connecting one to each of the circulation pumps 27y, 27m, and 27c to performing diagnosis, it is possible to further determine which circulation pump of YMC has failed.

According to this configuration, in the liquid ejection head including the plurality of circulation pumps, it is possible to independently diagnose each circulation pump.

### OTHER EMBODIMENTS

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer-executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims priority to Japanese Patent Application No. 2024-231016, which was filed on Dec. 26, 2024 and which is hereby incorporated by reference herein in its entirety.

What is claimed is:

1. A liquid ejection head including a piezoelectric pump for circulating ink, the liquid ejection head comprising:
a booster circuit configured to generate a boosted voltage for driving the piezoelectric pump in response to a driving signal;
a driving circuit configured to generate a pump driving signal for driving the piezoelectric pump based on the boosted voltage; and
a monitoring circuit configured to monitor a displacement of a boosted voltage output from the booster circuit,
wherein the monitoring circuit readably holds a result of monitoring the boosted voltage.

2. The liquid ejection head according to claim 1, wherein the monitoring circuit includes a detection circuit configured to detect whether the boosted voltage becomes higher than a first predetermined voltage and whether the boosted voltage becomes lower than a second predetermined voltage, and
a holding circuit configured to hold a result detected by the detection circuit.

3. The liquid ejection head according to claim 1, wherein the driving signal is a pulse signal,
the liquid ejection head further includes a generating circuit configured to change at least any of a period and a duty of the pulse signal in accordance with setting to output the pulse signal,
wherein the booster circuit generates the boosted voltage with power corresponding to the pulse signal.

4. The liquid ejection head according to claim 1, further comprising:
a capacitor, connected to an output of the booster circuit, configured to charge a charge by the boosted voltage.

5. The liquid ejection head according to claim 1, further comprising:
a liquid ejection head for monochrome printing; and
a plurality of liquid ejection heads for color printing,
wherein the driving circuit includes a first driving circuit that drives a piezoelectric pump of the liquid ejection head for monochrome printing, and a second driving circuit that drives a plurality of piezoelectric pumps of the plurality of liquid ejection heads.

6. A liquid ejecting apparatus including a liquid ejection head including a piezoelectric pump for circulating ink,
wherein the liquid ejection head comprising:
a booster circuit configured to generate a boosted voltage for driving the piezoelectric pump in response to a driving signal;
a driving circuit configured to generate a pump driving signal for driving the piezoelectric pump based on the boosted voltage; and
a monitoring circuit configured to monitor a displacement of a boosted voltage output from the booster circuit to hold a result of the monitoring, and
the liquid ejecting apparatus comprising:
one or more controllers including one or more processors and one or more memories, wherein the one or more controllers are configured to:
control the driving signal to lower a power of the boosted voltage generated by the booster circuit, and determine whether the liquid ejection head is normal based on the result held by the monitoring circuit, at a time of diagnosis of the liquid ejection head.

7. The liquid ejecting apparatus according to claim 6, wherein the monitoring circuit includes a detection circuit configured to detect whether the boosted voltage becomes higher than a first predetermined voltage and whether the boosted voltage becomes lower than a second predetermined voltage, and
a holding circuit configured to hold a result detected by the detection circuit.

8. The liquid ejecting apparatus according to claim 6, wherein the liquid ejection head further comprising:
a generating circuit configured to output a pulse signal that is the driving signal,
wherein the one or more controllers set, in the generating circuit, at least any of a period and a duty of the pulse signal so as to be shorter or lower than the at least any of the period and the duty of the pulse signal at a time of printing, at a time of diagnosis of the liquid ejection head, and
wherein the booster circuit generates the boosted voltage with power corresponding to the pulse signal.

9. The liquid ejecting apparatus according to claim 7, wherein the one or more controllers determine that the piezoelectric pump is not normal in a case where the result held in the holding circuit indicates that the boosted voltage has not become lower than the second predetermined voltage.

10. The liquid ejecting apparatus according to claim 7, wherein the one or more controllers determine that the booster circuit is not normal in a case where the result held in the holding circuit indicates that the boosted voltage has become higher than the first predetermined voltage.

11. The liquid ejecting apparatus according to claim 7, wherein the one or more controllers is able to set the first predetermined voltage and the second predetermined voltage.

12. The liquid ejecting apparatus according to claim 8, wherein the liquid ejection head including:
a liquid ejection head for monochrome printing; and
a plurality of liquid ejection heads for color printing,
wherein the driving circuit includes a first driving circuit that drives a piezoelectric pump of the liquid ejection head for monochrome printing, and a second driving circuit that drives a plurality of piezoelectric pumps of the plurality of liquid ejection heads, and
wherein the one or more controllers set, in the generating circuit, at least any of a period and a duty of the pulse signal so as to be shorter or lower than the at least any of the period and the duty of the pulse signal at a time of diagnosis of the plurality of liquid ejection heads, at a time of diagnosis of the liquid ejection head for monochrome printing.

13. The liquid ejecting apparatus according to claim 12, wherein the liquid ejection head further including:
a selection circuit configured to select any of the plurality of piezoelectric pumps driven by the second driving circuit,
wherein the one or more controllers select a piezoelectric pump that is a diagnosis target among the plurality of piezoelectric pumps by the selection circuit.

14. The liquid ejecting apparatus according to claim 8, wherein the pulse signal is a PWM signal.
